(19) United States
(12) Patent Application Publication
(10) Pub. No.: US 2024/0170459 A1
(43) Pub. Date: May 23, 2024

(54) SEMICONDUCTOR PACKAGE AND MANUFACTURING METHOD OF THE SAME

(71) Applicant: Samsung Electronics Co., Ltd., Suwon-si (KR)

(72) Inventors: Bo Hee HWANG, Suwon-si (KR); Young Kun JEE, Suwon-si (KR); Sang Cheon PARK, Suwon-si (KR)

(73) Assignee: Samsung Electronics Co., Ltd., Suwon-si (KR)

(21) Appl. No.: 18/502,569

(22) Filed: Nov. 6, 2023

(30) Foreign Application Priority Data
Nov. 21, 2022 (KR) 10-2022-0156392
Apr. 14, 2023 (KR) 10-2023-0049311

(51) Int. Cl. H01L 25/065; H01L 23/00; H01L 23/498

(52) U.S. Cl. CPC H01L 25/0657; H01L 23/49816; H01L 23/49822; H01L 24/08; H01L 24/97; H01L 2224/97; H01L 2924/1436; H10B 80/00

(57) ABSTRACT

A semiconductor package may include a package substrate, a stack die including a plurality of dies are stacked on the package substrate, a gap fill insulating layer on an upper surface of the stack die, a top dummy die on the gap fill insulating layer, and a molding portion surrounding the stack die having the top dummy die thereon.

### CROSS-REFERENCE TO RELATED APPLICATION

This application claims priority from Korean Patent Application No. 10-2022-0156392 filed on Nov. 21, 2022, and Korean Patent Application No. 10-2023-0049311 filed on Apr. 14, 2023 in the Korean Intellectual Property Office, and all the benefits accruing therefrom under 35 U.S.C. 119, the entire contents of which are herein incorporated by reference.

### BACKGROUND

### 1. Technical Field

The present disclosure relates to a semiconductor package.

### 2. Description of the Related Art

A recent trend in the electronics industry is to manufacture lightweight, miniaturized, high-speed, multifunctional, and high-performance products at reasonable prices. In order to achieve such an object, efforts are being made to improve the degree of integration of various semiconductor devices such as logic circuits and memories. As a method for integrating more components (e.g., semiconductor chips) into a package structure, a stacking technology such as a three dimensional integrated circuit (3D IC) is widely used.

Recently, direct bonding is used to vertically stack a plurality of dies, thereby reducing interconnection lengths between the stacked chips. However, during direct bonding, difficulties may occur in realizing flatness depending on the degree of stacking of dies.

### SUMMARY

Aspects of the present disclosure provide a semiconductor package with improved reliability and production yield and/or a manufacturing method of the same.

According to an embodiment of the present disclosure, a semiconductor package may include a package substrate, a stack die including a plurality of dies are stacked on the package substrate, a gap fill insulating layer on an upper surface of the stack die, a top dummy die on the gap fill insulating layer, and a molding portion surrounding the stack die having the top dummy die thereon.

According to an embodiment of the present disclosure, a manufacturing method of a semiconductor package may include forming a stack die by stacking dies on a package substrate; forming a gap fill insulating layer on an upper surface of the stack die, the gap fill insulating layer including oxide; bonding a top dummy die onto the gap fill insulating layer; and forming a molding portion covering the stack die to which the top dummy die is bonded.

According to an embodiment of the present disclosure, a semiconductor package may include a package substrate, a stack die including a plurality of dynamic random access memory (DRAM) chips stacked on the package substrate, a gap fill insulating layer on an upper surface of the stack die, a gap fill sidewall structure on a side surface of the stack die, a top dummy die on the gap fill insulating layer, and a molding portion surrounding the gap fill sidewall structure of the stack die.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail example embodiments thereof with reference to the attached drawings, in which:

FIG. 1 is a cross-sectional view for describing a semiconductor device according to some example embodiments.

FIGS. 2 to 8 are cross-sectional views each illustrating a manufacturing process of a semiconductor device according to some example embodiments.

FIG. 9 is a flowchart illustrating a manufacturing method of a semiconductor package according to some example embodiments.

### DETAILED DESCRIPTION

Expressions such as “at least one of,” when preceding a list of elements, modify the entire list of elements and do not modify the individual elements of the list. For example, “at least one of A, B, and C.” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Hereinafter, example embodiments of the present disclosure will be described with reference to the accompanying drawings.

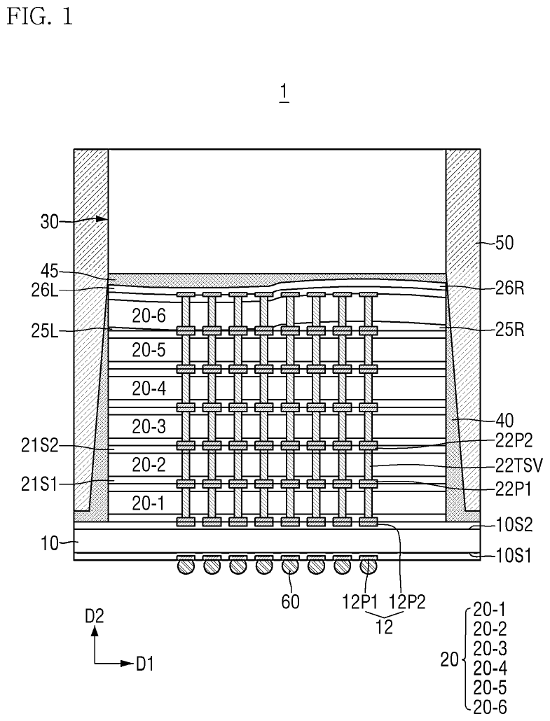

FIG. 1 is a cross-sectional view for describing a semiconductor device according to some example embodiments.

Referring to FIG. 1, a semiconductor package 1 may include a plurality of dies 20-1, 20-2, 20-3, 20-4, 20-5, and 20-6 (hereinafter, 20) stacked on a package substrate 10, a top dummy die 30 stacked on the plurality of dies 20, a gap fill sidewall structure 40 surrounding the plurality of dies 20, and a molding portion 50. The gap fill sidewall structure 40 may include an insulating material.

The package substrate 10 may include an upper pad 12P2 and a lower pad 12P1 respectively disposed on upper and lower surfaces of the package substrate 10. The package substrate 10 may further include insulating layers 10S2 and 10S1 on the upper and lower surfaces except for the upper and lower pads 12, respectively. The semiconductor package 1 may further include bumps 60 disposed on a lower side of the lower pad 12P1 of the package substrate 10 to connect to an external device. The bump 60 includes metal, for example, copper (Cu).

According to some example embodiments, the package substrate 10 may include a plurality of individual elements, and may include internal wirings (not illustrated) connecting the upper pad 12P2 and the lower pad 12P1 to the individual elements. According to some example embodiments, the package substrate 10 may include a printed circuit board or a silicon interposer substrate.

The semiconductor package 1 includes a plurality of dies 20 stacked from a first die 20-1 to a sixth die 20-6 in a vertical direction (e.g., a D2 direction). In this specification, the plurality of dies 20 stacked on the package substrate 10 are referred to as a stack die. According to various example embodiments, the stack die may be referred to as a memory chip, a slave chip, a DRAM dice, or a DRAM slice. Alternatively, according to various example embodiments, the stack die may be referred to as an HBM DRAM element or an HBM DRAM chip. Each of the dies 20 may have the same or similar structures, and a repeated description of the same or similar structures is omitted for convenience of description. The stack die may be used in a hybrid memory cube (HMC).

The dies 20-1, 20-1, 20-3, 20-4, 20-5, and 20-6 of each layer may include a die substrate body (see 20-2 for example), a through electrode 22TSV, a lower connection pad 22P1, and an upper connection pad 22P2. The through electrode 22TSV may be formed to penetrate through the die substrate body (e.g., 20-2) and the wiring layers 21S1 and 21S2. The upper connection pad 22P2 and the lower connection pad 22P1 are disposed at and electrically connected to both ends of the through electrode 22TSV. The through electrode has a pillar shape and may include a barrier film on an outer surface thereof and a buried conductive layer therein. The barrier film may include at least one material selected from Ti, TiN, Ta, TaN, Ru, Co, Mn, WN, Ni, and NiB. The buried conductive layer may include at least one material selected from Cu alloys such as Cu, CuSn, CuMg. CuNi, CuZn, CuPd, CuAu, CuRe, and CuW, W. W alloys, Ni, Ru, and Co. Meanwhile, a via insulation layer may be interposed between the through electrode 22TSV and the die substrate body (e.g., 20-2). The via insulating layer may be formed of, for example, an oxide film, a nitride film, a carbide film, a polymer, or a combination thereof.

The die substrate body (e.g., 20-2) may be, for example, a memory chip. Accordingly, the die substrate body (e.g., 20-2) may include a plurality of memory elements therein. The memory elements may include, for example, dynamic random access memory (DRAM), static random access memory (SRAM), flash memory, electrically erasable and programmable read-only memory (EEPROM), phase-change random access memory (PRAM), magnetic random access memory (MRAM), or resistive random access memory (RRAM) elements.

An upper wiring layer 21S2 including a plurality of individual elements (not illustrated) such as transistors and an insulating layer covering the individual elements with an insulating material may be formed on a first surface (e.g., an upper surface) of the die substrate body (e.g., 20-2). The plurality of individual elements may include various microelectronics devices, for example, a metal-oxide-semiconductor field effect transistor (MOSFET) such as a complementary metal-insulator-semiconductor (CMOS) transistor, system large scale integration (LSI), a micro-electro-mechanical system (MEMS), an active element, a passive element, etc.

The plurality of individual elements may be electrically connected to the through electrode 22TSV through the upper connection pad 22P2.

A lower wiring layer 21S1 including a multilayer wiring and an insulating layer filled with an insulating material between the multilayer wirings may be formed on a lower side of a second surface (e.g., a lower surface) of the die substrate body (e.g., 20-2), and the wiring layer may be electrically connected to the through electrode 22TSV through the lower connection pad 22P1.

In the stacked dies, the lower connection pads 22P2 of the upper die may be bonded to the upper connection pads 22P1 of the lower die through pad-to-pad bonding that makes contact in a one-to-one manner. The upper and lower pads are formed of copper (Cu), and thus the pad-to-pad bonding may also be referred to as Cu-to-Cu bonding.

The insulating layers of the upper wiring layer 21S2 and the lower wiring layer 21S1 may include silicon oxide. For example, the insulating materials of the upper wiring layer 21S2 and the lower wiring layer 21S1 may include at least one of silicon nitride (SiN), silicon carbide (SiC), silicon oxynitride (SiON), silicon carbonitride (SiCN), aluminum nitride (AlN), aluminum oxynitride (AlON), aluminum oxide (AlO), and aluminum oxide carbide (AlOC).

In the semiconductor package 1, as the dies 20 are continuously stacked in the D2 direction, the die stack may be distorted in the process of stacking the dies 20. For example, the upper die 20, upper wiring layers 26L and 26R, and lower wiring layers 25L and 25R may be distorted together. Depending on a distortion caused by stress, heights of the die stack on one side (e.g., the left side) in the D1 direction and on the other side (e.g., the right side) in the D1 direction may be different from each other. For example, the die left sides 25L and 26L may be distorted into negative bends that bend downward, and the die right sides 25R and 26R may be distorted into positive bends that bend upward. Accordingly, as the number of dies stacked in the die stack increases, an accumulated topology of the dies may increase.

The semiconductor package 1 may further include a gap fill insulating layer 45. For example, the gap fill insulating layer 45 may include silicon oxide, for example, silicon oxide that may be formed by an atomic layer deposition process. The gap fill insulating layer 45 may be formed through a spin on deposition (SOD) process. For example, the gap fill insulating layer 45 may be formed of tetrathoxysilane (TEOS). However, the gap fill insulating layer 45 is not limited thereto, and may also be formed of silicon oxide such as phosphosilicate glass (PSG), borophosphosilicate glass (BPSG), undoped SiO₂ (USG), tetraethyl orthosilicate (PE-TEOS), and high density plasma CVD (HDP-CVD).

Alternatively, for example, the gap fill insulating layer may also be formed of at least one of silicon nitride (SiN), silicon carbide (SiC), silicon oxynitride (SiON), silicon carbonitride (SiCN), aluminum nitride (AlN), aluminum oxynitride (AlON), aluminum oxide (AlO), and aluminum oxide carbide (AlOC).

The gap fill insulating layer 45 may be formed by, for example, a spin on deposition process. The gap fill insulating layer 45 may be formed according to the spin on deposition process to form a gap fill sidewall structure 40 on a side surface of the stack die. A material of gap fill sidewall structure 40 may include the same material as the gap fill insulating layer 45.

The gap fill insulating layer 45 may be formed to a thickness capable of including all bonding voids due to the accumulated topology of the stack die. For example, the gap fill insulating layer 45 may be formed to a thickness of about 1 μm. The gap fill insulating layer 45 may be etched through a planarization process. A surface step difference caused by the accumulated topology of the stack die may be removed through the planarization process.

The semiconductor package 1 may further include a top dummy die 30. The top dummy die 30 may have a greater thickness than the other stacked dies 20. For example, when the thickness of the die 20 is 50 to 55 μm, the thickness of the top dummy die 30 may be 200 to 500 μm. According to various example embodiments, the top dummy die 30 may be referred to as a dummy die, a top die, or a spacer die. The top dummy die 30 may be attached onto the gap fill insulating layer 45. As the top dummy die 30 is attached onto the gap fill insulating layer 45 that is planarized without voids, bonding quality with the stack die is improved, and heat is well dissipated by the gap fill insulating layer 45, so that thermal characteristics of the semiconductor package 1 may be improved.

The semiconductor package 1 may further include a molding portion 50. The molding portion 50 may be provided to cover side surfaces of the top dummy die 30 and the stack die 20. The molding portion 50 may include an insulating resin such as an epoxy molding compound (EMC) material.

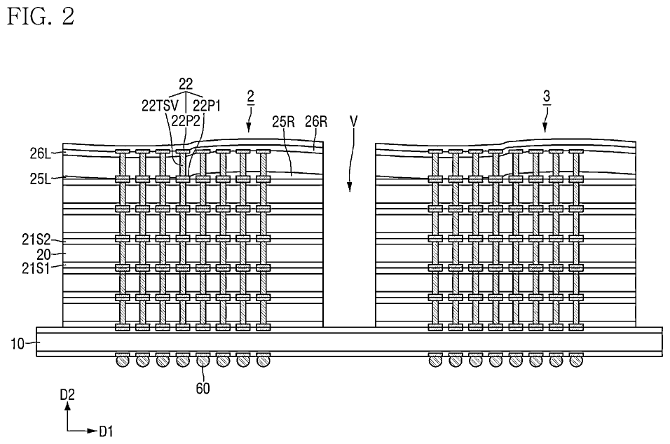

FIGS. 2 to 8 are cross-sectional views each illustrating a manufacturing process of a semiconductor device according to some example embodiments.

Referring to FIG. 2, in the semiconductor package 1, a package substrate 10 and at least two stack dies 2 and 3 disposed to be spaced apart from each other on the package substrate 10 may be disposed. Each of the stack dies 2 and 3 may include a plurality of dies 20 stacked in the D2 direction, and the number of dies included in each of the stack die 2 and the stack die 3 may be the same according to an example embodiment or may be different according to another example embodiment. According to some example embodiments, the stack dies 2 and 3 may include multiples of two dies. For example, the stack dies 2 and 3 each may include two stacked dies, four stacked dies, or eight stacked dies, but are not limited thereto.

Each of the stack dies 2 and 3 may be electrically connected to each other through through electrodes penetrating through the dies. For example, a first die of a first stack die may be connected to a second die on a lower side of the first die using lower connection pads provided on a lower surface of the first stack die. Second dies may be electrically connected to each other using the lower connection pads of the first die and upper connection pads provided on an upper surface of the second die. For example, the connection pads may be in the form of a micro pillar grid array (MPGA).

Although not illustrated, an adhesive (e.g., adhesive member or film) may be between the dies 20 (20-1 to 20-6) to bond adjacent dies 20 in the vertical direction to each other. For example, the adhesive (not shown) may bond a lower surface of the lower wiring layer 21S1 to an upper surface of the upper wiring layer 21S2 below, and the lower and upper connection pads 22P1 and 22P2 may extend through the adhesive.

The stack die 2 and the stack die 3 may be spaced apart from each other at a desired and/or alternatively predetermined interval in the D1 direction. As the stack dies 2 and 3 are disposed to be spaced apart from each other, a valley V may be formed.

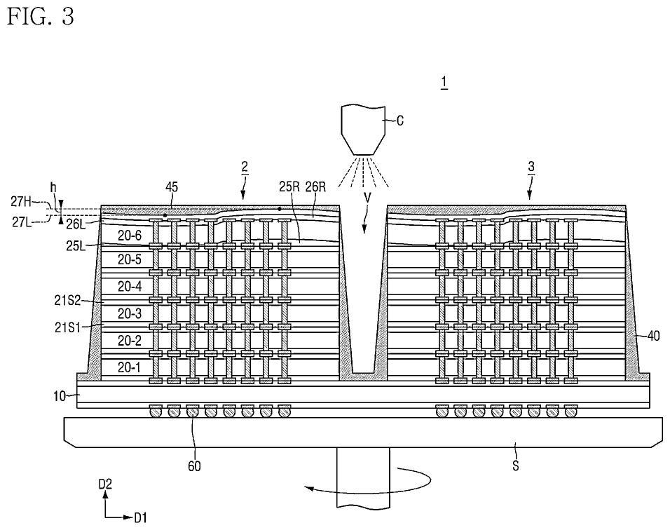

Referring to FIG. 3, in the semiconductor package 1, gap fill insulating layer 45 and gap fill sidewall structure 40 may be formed using a spin on deposition process. The package substrate 10 of FIG. 2 may be rotated on a base substrate S for spin, and oxide provided from the top of the semiconductor package 1 through a nozzle C may be deposited thereon. For example, the oxide provided through nozzle C may be formed of a silicon oxide film, a silicon nitride film, or a combination thereof.

The oxide provided through the nozzle C may include at least one of silicon nitride (SiN), silicon carbide (SiC), silicon oxynitride (SiON), silicon carbonitride (SiCN), aluminum nitride (AlN), aluminum oxynitride (AlON), aluminum oxide (AlO), and aluminum oxide carbide (AlOC).

The oxide is deposited on the stack dies 2 and 3 by a spin on deposition process.

For example, the gap fill insulating layer may be deposited to have a thickness capable of covering upper surface step difference according to the accumulated topology of the stack dies. When bonding voids are generated due to the accumulated topology of the stack die 2, the oxide is stacked to cover all of the upper surface step difference of the top die 20-6 among the stack dies.

For example, it is assumed that an upper surface of the top die 20-6 among the stack dies is bent due to the accumulated topology. Since a height of the upper surface of the top die 20-6 is not constant due to the bonding void, a surface step difference by h is generated between the lowest point 27L and the highest point 27H of the upper surface. The oxide 45 may be deposited from the lowest point 27L of the top die 20-6 to a height of the highest point 27H or more. That is, the oxide may be deposited from the highest point 27H of the upper surface of the top die to a desired and/or alternatively predetermined height.

According to some example embodiments, assuming that the void formed in the stack dies 2 and 3 is about 500 nm, the gap fill insulating layer 45 may be initially deposited to a thickness of about 1 μm by a spin on deposition manner. That is, the gap fill insulating layer 45 may be deposited by 1 μm or more from the highest point 27H of the top die 20-6.

Since the oxide 45 initially has a liquid or sol state, the oxide 45 has good gap fill characteristics and may reduce the steps caused by voids.

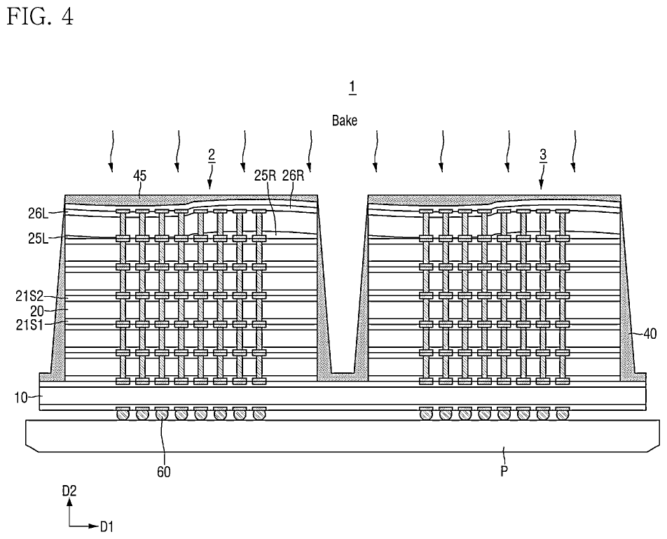

Referring to FIG. 4, the spin on deposited oxide may be cured by a bake and annealing process.

Accordingly, a gap fill insulating layer 45 may be formed on a portion of the package substrate 10 and the upper surfaces of the stack dies 2 and 3, and a gap fill sidewall structure 40 may be formed on side surfaces of the stack dies 2 and 3. According to some example embodiments, the gap fill sidewall structure 40 and the gap fill insulating layer 45 may be formed by curing the deposited oxide by performing a hard bake at a high temperature for several tens of minutes. The temperature should not exceed 300° C. and the time range should be 10˜20 minutes for the process.

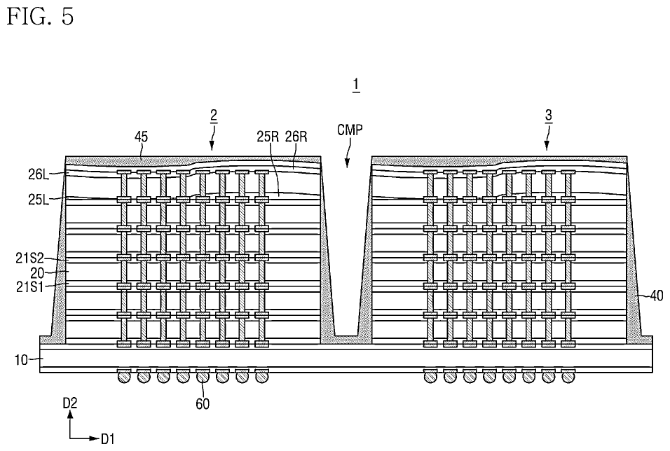

Referring to FIG. 5, the gap fill insulating layer 45 may be etched through a planarization process. The planarization process may be, for example, a chemical mechanical polishing (CMP) process. The slurry used in the CMP process may include, for example, an abrasive such as SiOx, AlxOy, or CexOy, and may have a PH value of, for example, 2 to 10.

According to some example embodiments, the CMP process polishes and planarizes the oxide deposited and cured to a desired and/or alternatively predetermined height from the highest point 27H of the top die 20-6 to a desired and/or alternatively predetermined thickness.

For example, the CMP process may polish the gap fill insulating layer 45 deposited to about 1 μm to about 200 to 300 nm. However, the example embodiments of the present disclosure are illustrative, and depending on the surface step difference according to the accumulated topology, the gap fill insulating layer 45 may be deposited at a height (or thickness) other than 1 μm from the highest point of the surface of the top die 20-6 according to various example embodiments, and accordingly, the polishing degree of the gap fill insulating layer 45 may also vary.

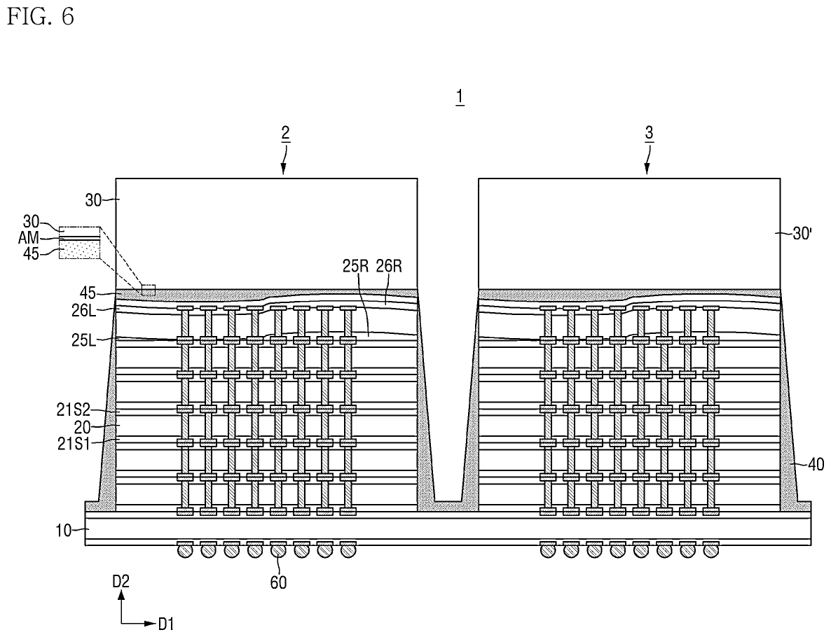

Referring to FIG. 6, a top dummy die 30 is stacked on the polished gap fill insulating layer 45. The top dummy die 30 may be bonded to the gap fill insulating layer 45 of the stack dies 2 and 3 using an adhesive member AM (e.g., adhesive layer). For example, when the thickness of the die 20 is 50 to 55 μm, the thickness of the top dummy die 30 may be 200 to 500 μm.

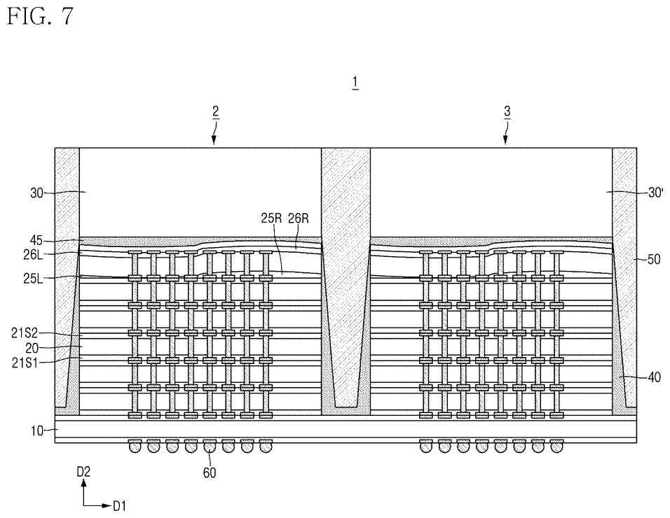

Referring to FIG. 7, a molding portion 50 may be disposed on the upper surfaces of the stack dies 2 and 3 to which the top die 30 is attached. In detail, the molding portion 50 may cover the upper surface of the substrate 10 and surround the stack dies 2 and 3. For example, an upper surface of the molding portion 50 may be coplanar with the upper surface of the top die 30 or may cover the upper surface of the top die 30. An adhesive member (see adhesive member AM in FIG. 6) may also be disposed between the top die 30 and the molding portion 50.

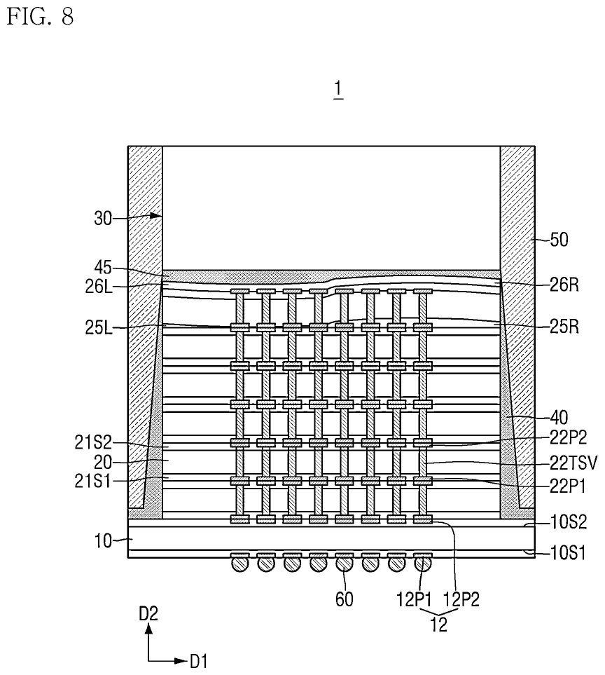

Referring to FIG. 8, a sawing process may be performed on the substrate 10. The sawing process may be set to cut within the molding portion between the stack dies 2 and 3. The manufacturing of the semiconductor package 1 may be completed through the sawing process.

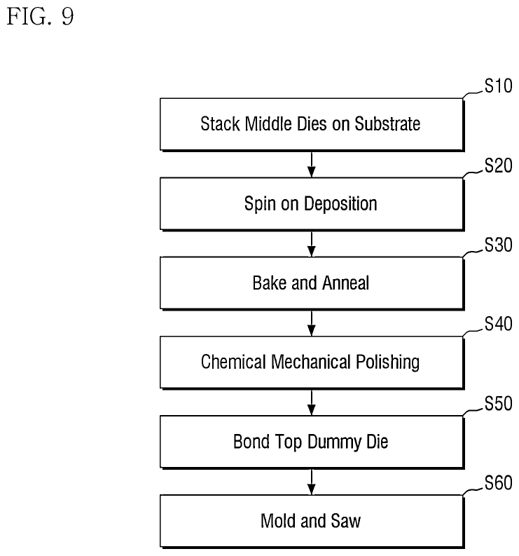

FIG. 9 is a flowchart illustrating a manufacturing method of a semiconductor package according to some example embodiments.

The semiconductor package 1 is formed by stacking a plurality of dies 20 on a package substrate 10 in a first direction (S10). The plurality of stack dies spaced apart from each other in the second direction may be simultaneously stacked on the package substrate 10. Each of the stack dies 2 and 3 may be electrically connected to each other through electrodes penetrating through the dies.

The package substrate 10 may be rotated on a base substrate S, and oxide may be deposited on the top of the stack die (S20). The deposited oxide may be heated to a desired and/or alternatively predetermined temperature and annealed (S30) to form a gap fill insulating layer. The gap fill insulating layer may be formed to be thick enough to all cover an accumulated topology of the stack dies.

Upper surfaces of the gap fill sidewall structure 40 and gap fill insulating layer 45 may be planarized through a chemical mechanical polishing process (S40). A top dummy die 30 is bonded to the planarized gap fill insulating layer 45 by an adhesive member (S50).

The stack die to which the top dummy die 30 is bonded is surrounded by a molding member, and a sawing process for separating each of the stack dies spaced apart in the second direction is performed (S60). After the sawing process, as illustrated in FIG. 1, the semiconductor package separated for each stack die is manufactured.

Example embodiments of the present disclosure have been described above with reference to the accompanying drawings, but the present disclosure may be implemented in various different forms, and those skilled in the art to which the present disclosure pertains may understand that the present disclosure may be implemented in other specific forms without changing the spirit and scope of the present disclosure. Therefore, it should be understood that the example embodiments described above are illustrative in all aspects and not restrictive.

What is claimed is:

1. A semiconductor package comprising:
a package substrate;
a stack die including a plurality of dies are stacked on the package substrate;
a gap fill insulating layer on an upper surface of the stack die;
a top dummy die on the gap fill insulating layer; and
a molding portion surrounding the stack die having the top dummy die thereon.

2. The semiconductor package of claim 1, wherein the gap fill insulating layer is formed by a spin on deposition process.

3. The semiconductor package of claim 2, wherein the gap fill insulating layer includes at least one of TEOS, PSG, BPSG, USG, PE-TEOS, and an HDP-CVD oxide.

4. The semiconductor package of claim 2, wherein
a thickness of the gap fill insulating layer covers a surface step difference of an upper surface of a top die in the stack die according to an accumulated topology of the stack die.

5. The semiconductor package of claim 4, wherein
the gap fill insulating layer is an oxide, and
an upper surface of the gap fill insulating layer is level with a highest point of the upper surface of the top die according to the accumulated topology.

6. The semiconductor package of claim 5, wherein the gap fill insulating layer has a planarized upper surface.

7. The semiconductor package of claim 6, further comprising:
an adhesive member, wherein
the adhesive member connects the top dummy die to the planarized upper surface of the gap fill insulating layer.

8. The semiconductor package of claim 1, further comprising:
a gap fill sidewall structure connected to the gap fill insulating layer and surrounding a side surface of the stack die.

9. The semiconductor package of claim 8, wherein the molding portion surrounds the gap fill sidewall structure of the stack die.

10. A manufacturing method of a semiconductor package, the manufacturing method comprising:
forming a stack die by stacking dies on a package substrate;
forming a gap fill insulating layer on an upper surface of the stack die, the gap fill insulating layer including oxide;
bonding a top dummy die onto the gap fill insulating layer; and
forming a molding portion covering the stack die to which the top dummy die is bonded.

11. The manufacturing method of claim 10, wherein
the gap fill insulating layer is formed by depositing silicon oxide on the stack die by a spin on deposition process to provide a deposited silicon oxide and by baking and annealing the deposited silicon oxide.

12. The manufacturing method of claim 11, wherein the spin on deposition process forms the gap fill insulating layer on the upper surface of the stack die and a gap fill sidewall structure surrounding a side surface of the stack die.

13. The manufacturing method of claim 12, wherein the molding portion is formed to surround the gap fill sidewall structure of the stack die.

14. The manufacturing method of claim 11, wherein the silicon oxide is at least one of TEOS, PSG, BPSG, USG, PE-TEOS, and an HDP-CVD oxide.

15. The manufacturing method of claim 10, further comprising:
performing a sawing process of cutting a part of the molding portion between the stack die and an other stack die spaced apart from each other, wherein
the forming the stack die includes forming the stack die spaced apart from the other stack die on the package substrate.

16. The manufacturing method of claim 10, wherein the molding portion includes an epoxy mold compound.

17. The manufacturing method of claim 10, wherein the dies include a dynamic random access memory (DRAM) chip.

18. The manufacturing method of claim 10, wherein the gap fill insulating layer and the gap fill sidewall structure are formed using silicon oxide by a spin on deposition process.

19. The manufacturing method of claim 18, wherein
the gap fill insulating layer is planarized by a chemical mechanical polishing process to provide a planarized gap fill insulating layer, and
the top dummy die is bonded to the planarized gap fill insulating layer.

20. A semiconductor package comprising:
a package substrate;
a stack die including a plurality of dynamic random access memory (DRAM) chips stacked on the package substrate;
a gap fill insulating layer on an upper surface of the stack die;
a gap fill sidewall structure on a side surface of the stack die;
a top dummy die on the gap fill insulating layer; and
a molding portion surrounding the gap fill sidewall structure of the stack die.
